(19) United States
(12) Patent Application Publication
(10) Pub. No.: US 2008/0258067 A1
(43) Pub. Date: Oct. 23, 2008

(54) Microelectronic System with a Passivation Layer

(75) Inventors: Gereon Vogtmeier, Aachen (DE); Roger Steadman Booker, Aachen (DE); Guenter Zeitler, Aachen (DE); Klaus Jurgen Engel, Aachen (DE); Herfried Karl Wieczorek, Aachen (DE)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N.V., Eindhoven (NL)

(21) Appl. No.: 11/573,716

(22) PCT Filed: Aug. 11, 2005
(86) PCT No.: PCT/IB05/52673

§ 371 Date: Jun. 13, 2008

(30) Foreign Application Priority Data
Aug. 20, 2004 (EP) 04104024.7

(51) Int. Cl. G01T 1/24; H01L 31/18; H01L 31/08

(52) U.S. Cl. 250/370.09; 250/370.11; 438/57; 257/E31.092

(57) ABSTRACT

The invention relates to a microelectronic system, particularly for an X-ray detector, comprising a semiconductor layer (1) with an array of pixels (P) which are composed of photosensitive components (3) and associated electronic circuits (4). An insulating passivation layer (5) with recesses (5a) in its surface is disposed between the semiconductor layer (1) and a scintillator (8). A shielding metal (6) for the protection of the electronic circuits (4) from X-radiation may be disposed in the recesses (5a) of the passivation layer (5). Furthermore, the recesses may contain glue for the fixation of the scintillator (8), wherein the passivation layer (5) additionally serves as a spacer between scintillator (8) and semiconductor layer (1).

The invention relates to a microelectronic system with a semiconductor layer and a passivation layer. The invention further relates to an X-ray detector containing such a microelectronic system, an imaging system with such an X-ray detector, and methods for the production of a microelectronic systems.

Microelectronic systems comprising integrated circuits (ICs) with a layer of electronic components realized at least partially in semiconductor technology, e.g. CMOS, are for example used in X-ray detectors of medical imaging systems. One problem associated with these ICs is that they are exposed to X-radiation which may interfere with sensitive electronic circuits on the chip. Therefore, an appropriate shielding must often be provided for these circuits (cf. WO 00/25149 A1). Another problem is associated with detectors of the so-called indirect conversion type which contain a scintillator for the conversion of X-rays into visible photons. Said scintillator must be fixed upon the surface of the integrated circuit at a well defined and uniform distance in order to guarantee an accurate function of the resulting detector. In this respect it is proposed in the EP 1 217 387 A2 to dispose spacers, e.g. metal wires or bumps, on the surface of the chip that are embedded into glue for fixing the scintillator.

Based on this situation it was an object of the present invention to provide a microelectronic system with a simple design that is particularly suited for the realization of X-ray detectors.

This object is achieved by a microelectronic system according to claim 1, an X-ray detector according to claim 7, an imaging system according to claim 8, and a method according to claim 9. Preferred embodiments are disclosed in the dependent claims.

The microelectronic system according to the present invention may in general be any microelectronic chip that is designed to provide a certain functionality, particularly a chip of an X-ray sensitive detector of the direct or indirect conversion type. The microelectronic system comprises the following components:

a) A so-called “semiconductor layer” with electronic components, wherein said components are mainly realized in semiconductor material (e.g. crystalline silicon) and by semiconductor technology (e.g. deposition, doping etc.).

b) A passivation layer that is disposed on top of the aforementioned semiconductor layer and that comprises recesses in its surface. The passivation layer consists of an insulating material and is usually applied in microelectronics in order to protect and isolate different components of an integrated circuit. The recesses may for example be produced by mask etching in the flat free surface of a passivation layer after its deposition. The thickness of the passivation layer may be chosen according to the requirements of the individual application, for example relatively thick for Micro-Electro-Mechanical Systems (MEMS) and relatively thin for ICs. In typical cases, it ranges from 10 μm to 5000 μm, particularly from 50 μm to 1000 μm. Furthermore, the passivation layer may consist of two or more sub-layers of different materials, whereby definite stops can be achieved during etching processes.

c) At least one specific material (i.e. a material other than the typical materials of the semiconductor layer and the passivation layer) that is disposed in the aforementioned recesses of the passivation layer. Important examples of specific materials and the advantages achieved by their integration into the passivation layer are discussed below in connection with preferred embodiments of the invention. Preferably, the specific material fills the recesses exactly, thus replacing the lacking passivation material and producing a flat common surface of passivation layer and specific material. In this case, further components with a flat underside may be placed tightly upon the passivation layer. If more than one specific material is used, it may be homogeneous or inhomogeneous (e.g. arranged in layers).

According to first preferred embodiment of the invention, the specific material is a glue (adhesive) with which an additional component is fixed upon the passivation layer. In this case the passivation layer fulfills the function of a precisely fabricated spacer which guarantees a well defined and uniform distance between the semiconductor layer and the additional component, and the glue cannot cause any irregularities in the spacing due to its localization in the recesses of the passivation layer. Moreover, a more accurate positioning of the additional component in the direction parallel to the passivation layer can be achieved due to the precisely positioned recesses. The additional component may for example be a scintillator that is fixed upon a photosensitive chip in order to yield an X-ray detector of the indirect conversion type.

According to another embodiment of the invention, which may of course be combined with the aforementioned one, the specific material is a shielding material for the protection of sensitive electronic components in the semiconductor layer from radiation. Depending on the particular application, the shielding material is chosen appropriately to be able to absorb or reflect the desired spectrum of radiation, for example radiofrequency (RF) or ultraviolet (UV). An important example is the shielding of X-radiation, in which case the shielding material is a heavy metal like tantalum, tungsten, lead or bismuth with a high atomic number Z.

According to a further development of the aforementioned embodiment, the shielding material has at least partially a surface that is reflective for certain parts of the electromagnetic spectrum, for example the same or a different spectrum as that to be blocked by the shielding material. An important example for the reflection of a different radiation is a heavy metal with a white surface, wherein the metal absorbs X-radiation and the white surface reflects visible photons that were generated by the conversion of X-radiation in a scintillator. Due to their reflection, the photons are not lost for the detection process, thus improving the sensitivity or DQE (Detective Quantum Efficiency) of the detector.

The semiconductor layer may particularly comprise a regular pattern (e.g. a matrix) of sensor elements or pixels, wherein each pixel comprises an electronic circuit and a photosensitive component, and wherein said photosensitive component produces signals under irradiation that are processed by the electronic circuit. Such a design is for example used in X-ray detectors, wherein the pixels may be sensitive to X-radiation (direct conversion) or secondary photons of visible light (indirect conversion). A typical problem of such detectors is that the electronic circuits in the pixels can be impaired by X-radiation. This problem can be avoided by the proposed microelectronic system if a pattern of recesses in the passivation layer with a shielding material therein is produced that lies just above the sensitive electronic circuits in order to protect them from X-rays.

According to a further development of the aforementioned embodiment, the specific material in the passivation layer encircles the pixels. The material may then both shield components of the semiconductor layer from X-radiation and simultaneously prevent crosstalk between different pixels, i.e. the spreading of photons from one pixel to neighboring pixels.

The invention further comprises an X-ray detector with at least one X-ray sensitive microelectronic system or chip containing

a) a semiconductor layer with electronic components;

b) a passivation layer on top of the semiconductor layer with recesses in its surface;

c) at least one specific material that is disposed in the recesses of the passivation layer.

Furthermore, the invention relates to an imaging system that comprises an X-ray detector of the aforementioned kind. The imaging system may particularly be a PET (Positron Emission Tomography) or SPECT (Single Photon Emission Computed Tomography) device or an X-ray device like a CT (Computed Tomography) system.

The X-ray detector and the imaging system are based on a microelectronic system of the kind described above. Therefore, reference is made to the preceding description for more information on the details, advantages and improvements of the detector and the imaging system.

Moreover, the invention comprises a method for the production of a microelectronic system with the following steps:

a) Production of a semiconductor layer with electronic components. This step may in principle apply all methods known from semiconductor technology.

b) Deposition of a passivation layer on top of the semiconductor layer, wherein the passivation layer has recesses in its surface.

c) Deposition of at least one specific material in the recesses of the passivation layer. The specific material may for example be a metal that is cut or punched from a foil and put into the recesses or that is printed onto the surface of the passivation layer.

With the method a microelectronic system of the kind described above can be produced. Therefore, reference is made to the preceding description for more information on the details, advantages and improvements of that method.

According to a further development of the method, the recesses are etched into the free surface of the passivation layer after the deposition of the (flat) passivation layer on top of the semiconductor layer. Such etching may be done by the usual methods known in the state of the art, particularly by using masks for generating structures that match structures in the semiconductor layer.

The method may be extended to allow the production of microelectronic systems with regions of a material containing at least one metal component, particularly of microelectronic systems of the kind mentioned above. To this end, the method comprises the deposition of said material on a carrier in a fluid state and the subsequent solidification of the deposited material. The material may particularly be a shielding for sensitive electronic components and for example comprise a heavy metal that absorbs X-rays.

The aforementioned material may preferably be brought into its fluid state by melting the metal component(s) (e.g. lead), by suspending particles of the metal component(s) in a fluid (e.g. water), and/or by dissolving a salt of the metal component(s). If a molten metal is used, a component that changes the surface tension in the molten state may optionally be added (e.g. tin Sn may be added to lead Pb in order to increase its surface tension). A further advantage of such an additive may arise from a lowering of the melting point.

According to a further development of the method, the fluid material is deposited or printed on its carrier in the form of droplets. This may particularly be achieved by technologies that are known from ink jet printing.

One such technology is for example described in the U.S. Pat. No. 4,828,886 which is incorporated into the present specification by reference. In this technology a molten material (e.g. a lead-tin alloy) is provided in a glass tube with a nozzle, wherein the tube can be compressed by a piezoelectric transducer, thus propelling droplets through said nozzle.

Another technology is described in the U.S. Pat. No. 6,531,191 B1 which is incorporated into the present specification by reference, too. According to this document, a particle-charged liquid is printed onto a surface by an ink jet printer. After said printing, the liquid is evaporated and the particles are sintered by irradiation with laser light.

In the following the invention is described by way of example with the help of the accompanying drawings in which:

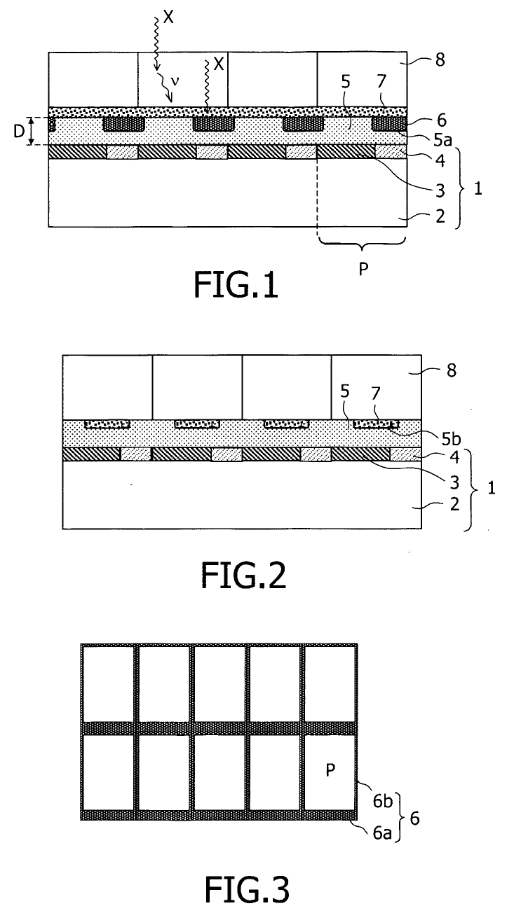

FIG. 1 shows a diagrammatic section (not to scale) through a part of an X-ray detector with metal shieldings for sensitive electronic components;

FIG. 2 shows a similar diagrammatic section through a part of an X-ray detector with recesses for glue;

FIG. 3 shows a top view of the detector of FIG. 1.

In the figures, like numerals refer to like components and are therefore explained only once.

In the following the invention will be explained with reference to the example of an X-ray detector of the indirect conversion type as it may for example be used in a CT system, though the invention is not restricted to such an application. The basic design of such an X-ray detector is for example described in the WO 00/25149 A1 which is incorporated into the present application by reference.

The detector shown in FIG. 1 comprises a microelectronic system or (micro)chip with a layer 1 that is designated here as “semiconductor layer” because it comprises a carrier or bulk material 2 based on a semiconductor material like silicon Si. On the top of the bulk material 2, electronic components are fabricated according to methods like deposition, doping and the like that are well known in the art of microelectronics and semiconductor technology. Preferably, the circuits are made in CMOS technology and arranged in a regular pattern of pixels P that can be individually addressed and read out by an associated logic (not shown). Each pixel P comprises a photosensitive component 3 that produces an electrical signal proportional to the amount of optical photons v absorbed by it. The photosensitive component may for example be a photodiode or phototransistor. The signals produced by the photosensitive components 3 are in each pixel processed by associated electronic circuits 4, for example amplified.

The topmost layer of the detector is a scintillation layer or scintillator 8 with an array of individual scintillator crystals (e.g. of CdWO₄ or Gd₂O₂S:Pr, F, Ce) that are fixed to the underground by a layer of glue 7. In the scintillator 8, incident X-radiation X is converted into optical photons v. Those of the photons v which reach the photosensitive components 3 in the semiconductor layer 1 are detected and provide an indication of the amount and location of the original X-radiation.

There are two principal problems associated with an X-ray detector of the aforementioned kind which are addressed by the present invention. The first kind of problem results from the fact that the electronic circuits 4 may be sensitive to X-rays and can therefore be disturbed if X-ray quanta X pass the scintillator 8 without conversion (or are generated in the scintillator by X-ray fluorescence) and reach the electronic circuits 4. In order to shield the electronic circuits 4 from such X-radiation, it is known in the state of the art to place spacers of heavy metal between the scintillator crystals 8 and to arrange the electronic circuits under said spacers. The volume of the scintillator is then however reduced by the volume of the spacers, yielding a decreased DQE. Moreover, reflector layers have to be disposed on both sides of the heavy metal spacers in order to reflect photons v back into the scintillator crystals and to avoid crosstalk. The resulting sandwich structure of several materials is difficult to produce with the required high accuracy.

The aforementioned problem is circumvented by the design shown in FIG. 1. According to this design, a passivation layer 5 of an insulating material (transparent to photons v) is deposited upon the semiconductor layer 1. The thickness D of that passivation layer 5 typically ranges from 50 μm to 1 mm. The passivation layer 5 may particularly consist of a special photoresist like the epoxy based photoresist SU8 which is well known in the MEMS technology for structuring and which can be processed with etching optical exposed mask geometries. Of course other photoresists may be used as well (see for example products available from MicroChem Corp., Newton, Mass., USA; Rohm and Haas Electronic Materials, Buxton, England). Therefore, a pattern of recesses 5a can be etched into the (originally flat) upper surface of the passivation layer 5, wherein one recess 5a is located above each X-ray sensitive electronic circuit 4 in the semiconductor layer 1.

In the next step, a shielding metal with a high Z number like W or Pb can be placed into the recesses 5a of the passivation layer 5. According to one of several possible methods, pieces of the shielding metal may be cut or punched from a thin foil and then be placed into the recesses 5a like the pieces of a puzzle.

The minimum required thickness of the metal shield 6 depends on the radiation hardness of the circuit 4 and the protection demands. Typically its thickness is smaller or equal to the thickness of the passivation layer 5. To get a flat surface for the whole chip it is necessary to use a very thick passivation layer 5 that is etched down only in the areas 5a where the metal shield shall be placed.

Optionally, there can be a white reflection coating at the top side of the metal shield 6 that reflects light coming from the scintillator 8 back, so that there is no optical loss of photons v in the metal mask.

Depending on the geometry of the shielding 6 at the same time an optical pixel crosstalk in the gap between scintillator 8 and chip could be reduced if the flatness of the surface of the chip is at the same height as the metal 6 and the metal border surrounds the whole pixel. Then only the thickness of the glue layer 7 is relevant. This glue layer 7 should be very thin to avoid crosstalk and the refraction index of the glue should match the refraction index of the passivation layer 5. Moreover, the passivation layer 5 could be designed as an antireflection layer to optimize the coupling of the light from the scintillator 8 into the photodiode 3.

A great advantage of the design of FIG. 1 is that the DQE of the pixel is improved as the volume of the conversion material 8 is larger and the coupling to the diode 3 is better. Moreover, the separator between the scintillator crystals 8 can be simplified to be just a reflector material having only the function to reduce crosstalk.

FIG. 3 shows a top view of a part of the X-ray detector of FIG. 1 with the scintillator 8 and the glue layer 7 being removed. It can be seen that the chip consists of a matrix of pixels P and that the shielding metal 6 has a part 6a that is disposed above the electronic circuits 4 and a part 6b that encircles the area of the pixel P to avoid crosstalk.

Another problem that is addressed by the present invention is related to the fixation of a scintillation layer 8. Typically, a scintillation layer 8 is fixed upon a chip as shown in FIG. 1 with an intermediate layer 7 of a glue. In this case, it is very difficult to provide an accurate positioning of the scintillator 8 above the semiconductor layer 1 and an uniform, homogeneous thickness of the glue layer. A solution to this problem is shown in FIG. 2. As before, a thick (up to 50 μm) passivation layer 5 is deposited on top of the semiconductor layer 1 (eventually with two different materials to have a defined stop for plasma etching) and etched down again in accurately positioned areas 5b where a glue should be placed. The structures which are not etched or which are only etched down to a defined distance can then serve as a spacer between the semiconductor layer 1 and the scintillator 8 and as marks for an exact alignment of the scintillator 8. Different geometries can be realized with different masks and different etching times. Moreover, it is possible to implement the geometry of a wall or a cross-structure for alignment purposes.

It should be noted that the designs of FIGS. 1 and 2 may of course be combined and are only depicted in different Figures for reasons of clarity. Therefore, the design of FIG. 2 may be modified by the addition of recesses 5a in which a shielding material is disposed.

Finally it is pointed out that in the present application the term “comprising” does not exclude other elements or steps, that “a” or “an” does not exclude a plurality, and that a single processor or other unit may fulfill the functions of several means. Moreover, reference signs in the claims shall not be construed as limiting their scope.

1. A microelectronic system, comprising
a) a semiconductor layer with electronic components;
b) a passivation layer on top of the semiconductor layer with recesses in its surface;
c) at least one specific material that is disposed in the recesses of the passivation layer.

2. The microelectronic system according to claim 1, wherein the specific material is a glue with which an additional component, particularly a scintillator, is fixed upon the passivation layer.

3. The microelectronic system according to claim 1, characterized in that the specific material is a shielding material, particularly a heavy metal, for shielding sensitive electronic components in the semiconductor layer from radiation.

4. The microelectronic system according to claim 3, wherein the shielding material has at least partially a reflective surface.

5. The microelectronic system according to claim 1, wherein the semiconductor layer comprises a regular pattern of pixels, each of which contains an electronic circuit for the processing of signals produced by an associated photosensitive component.

6. The microelectronic system according to claim 5, wherein the specific material encircles the pixels.

7. X-ray detector, comprising at least one X-ray sensitive microelectronic system with
a) a semiconductor layer with electronic components;
b) a passivation layer on top of the semiconductor layer with recesses in its surface;
c) at least one specific material that is disposed in the recesses of the passivation layer.

8. Imaging system, particularly an X-ray, CT, PET, or SPECT device, comprising an X-ray detector according to claim 7.

9. A method for the production of microelectronic systems, comprising the following steps:
a) production of a semiconductor layer with electronic components;
b) deposition of a passivation layer on top of the semiconductor layer with recesses in its surface;
c) deposition of at least one specific material in the recesses of the passivation layer.

10. The method according to claim 9, wherein the recesses are etched into the passivation layer after its deposition.

11. The method according to claim 9, comprising the deposition of a material containing at least one metal component on a carrier in a fluid state and the subsequent solidification of the deposited material.

12. The method according to claim 11, wherein the material is brought into its fluid sate by melting the metal, by suspending particles of the metal in a fluid, and/or by dissolving a salt of the metal.

13. The method according to claim 11, wherein the fluid material is deposited on its carrier in the form of droplets.
